(19) United States
(12) Patent Application Publication
(10) Pub. No.: US 2012/0134382 A1
(43) Pub. Date: May 31, 2012

(54) SURFACE EMITTING SEMICONDUCTOR LASER COMPONENT HAVING A VERTICAL EMISSION DIRECTION

(75) Inventors: Bernd Mayer, Regensburg (DE); Andreas Koller, Kallmünz (DE); Joachim Pfeiffer, Obertraubling (DE)

(73) Assignee: OSRAM OPTO SEMICONDUCTORS GMBH, Regensburg (DE)

(21) Appl. No.: 13/127,126

(22) PCT Filed: Aug. 26, 2009
(86) PCT No.: PCT/DE2009/001214

§ 371 Date: May 24, 2011

(30) Foreign Application Priority Data
Nov. 5, 2008 (DE) 10 2008 055 941.5

(51) Int. Cl. H01S 5/10

(52) U.S. Cl. 372/46.013

(57) ABSTRACT

A surface emitting semiconductor laser component having a vertical emission direction includes a semiconductor body having a first resonator mirror, a second resonator mirror, and an active zone that generates radiation, wherein the first resonator mirror has alternately stacked first layers having a first composition and second layers having a second composition, the first layers have oxidized regions, at least the first layers each contain a dopant, and at least one layer of the first layers has a dopant concentration different from the dopant concentration of the other first layers.

### RELATED APPLICATIONS

This is a §371 of International Application No. PCT/DE2009/001214, with an international filing date of Aug. 26, 2009 (WO 2010/051784 A2, published May 14, 2010), which is based on German Patent Application No. 10 2008 055 941.5, filed Nov. 5, 2008, the subject matter of which is incorporated by reference.

### TECHNICAL FIELD

This disclosure relates to a surface emitting semiconductor laser component having a vertical emission direction, which component is provided for generating laser radiation by an internal optical resonator.

### BACKGROUND

Surface emitting semiconductor laser components having a semiconductor body are known, inter alia, in which the current path within the semiconductor body is routed in a targeted manner, for example, by oxidation apertures arranged in the edge region of the semiconductor body. Semiconductor lasers having oxidation apertures are known, for example, from “Dependence of lateral oxidation rate on thickness of AlAs-layer of interest as a current aperture in vertical-cavity surface-emitting laser structures,” Journal of Applied Physics, Vol. 84, No. 1, Jul. 1, 1998.

Oxidation apertures formed in semiconductor layers each have a lateral extent, wherein conventionally the lateral extent of the oxidation apertures in the individual semiconductor layers is approximately of the same magnitude.

It could therefore be helpful to provide a surface emitting semiconductor laser component which has improved component properties, is distinguished, in particular, by an improved reproducibility of the lateral extent of the oxidation apertures and at the same time exhibits an improved oxidation homogeneity.

### SUMMARY

We provide a surface emitting semiconductor laser component having a vertical emission direction including a semiconductor body having a first resonator mirror, a second resonator mirror, and an active zone that generates radiation, wherein the first resonator mirror has alternately stacked first layers having a first composition and second layers having a second composition, the first layers have oxidized regions, at least the first layers each contain a dopant, and at least one layer of the first layers has a dopant concentration different from the dopant concentration of the other first layers.

### BRIEF DESCRIPTION OF THE DRAWINGS

FIG. 1A shows a schematic cross section of a first example of a semiconductor laser component.

FIG. 1B shows a schematic cross section of a further example of a semiconductor laser component.

FIG. 2 shows a schematic excerpt from the semiconductor laser component.

FIG. 3 shows a diagram that plots the extent of the oxidized regions of the first layers against the dopant concentration of the second resonator mirror.

### DETAILED DESCRIPTION

We provide a surface emitting semiconductor laser component having a vertical emission direction which comprises a semiconductor body having a first resonator mirror, a second resonator mirror and an active zone suitable for generating radiation. The first resonator mirror has alternately stacked first layers having a first composition and second layers having a second composition. The first layers have oxidized regions. Furthermore, at least the first layers each contain a dopant, wherein at least one layer of the first layers has a dopant concentration that is different from the dopant concentration of the other first layers.

The composition of a layer is defined by elements contained in the layer and also the nominal (i.e., within the scope of the accuracy of the composition monitoring during or after the growth process) stoichiometry thereof, dopants and impurities not being concomitantly taken into account. The stoichiometry is given by the content (proportion) of the individual elements in the layer.

The surface emitting semiconductor laser component is a surface emitting semiconductor laser with a vertical resonator (VCSEL: Vertical Cavity Surface Emitting Laser). In particular, the main emission direction of the component runs perpendicularly to the main extension plane of the semiconductor layers of the semiconductor body.

The semiconductor laser component is provided for generating laser radiation by an internal optical resonator. The first resonator mirror, the second resonator mirror and the active zone each preferably have a lateral main extension axis.

The current path of the semiconductor body is delimited by oxidation apertures. Oxidation apertures arise, for example, as a result of oxidized regions in the first layers of the first resonator mirror. For this purpose, in particular the layers of the resonator mirror which preferably contain AlₓGa₁₋ₓAs where 0.95≦x≦1 are oxidized laterally by an oxidation process. In particular, the layers are oxidized in the edge region of the semiconductor body.

As a result of the oxidation process, the layers lose current conductivity in these regions. As a result, the current flow through the semiconductor body can advantageously be locally delimited. In particular, the semiconductor body has, in the edge region, virtually no or at least a lower current flow than in the non-oxidized regions.

On account of the oxidation apertures, the pump current density is preferably greater in the central region of the semiconductor body than in the edge region of the semiconductor body. The pump current density can substantially have a quasi-Gaussian profile having a maximum in the central region, having—proceeding from the maximum—comparatively flat flanks in the central region and steepening flanks in the edge region.

Layers of the first resonator mirror, preferably at least the first layers, each contain a dopant, wherein at least one layer of the first layers has a dopant concentration that is different from the dopant concentration of the other first layers.

In particular, the first layers of the resonator mirror therefore have at least two layers whose dopant concentration is different. The further first layers can substantially have the same dopant concentration as one of the at least two layers.

The dopant concentration influences the oxidation process in the first layers of the first resonator mirror, in particular the lateral extent of the oxidized regions. Preferably, the dopant concentration in the first layers of the first resonator mirror is formed such that the oxidized regions have an envisaged lateral extent. By the dopant concentration in the first layers of the first resonator mirror, it is accordingly possible to define the lateral extent of the oxidized regions in these layers. A good reproducibility of the lateral extent of the oxidized regions in the first layers of the first resonator mirror is thereby advantageously made possible. Essential component properties such as, for example, the series resistance, threshold voltage, threshold current and efficiency can therefore be influenced advantageously depending on the dopant concentration in the first layers.

Furthermore, the oxidation homogeneity can be improved by a targeted setting of the dopant concentration in the first layers of the first resonator mirror. As a result of an improved oxidation homogeneity in the first layers of the first resonator mirror, the component properties of the semiconductor laser component are furthermore advantageously improved.

Preferably, the oxidized region of the at least one layer having a dopant concentration that is different from the dopant concentration of the other first layers has a lateral extent that is different from the lateral extent of the other first layers.

Preferably, the lateral extent of the oxidized regions of the at least one layer deviates from the lateral extent of the other first layers by at least 1 μm.

Preferably, the first layers have two layers that differ from the other first layers in terms of the dopant concentration.

Particularly preferably, the dopant concentrations of the two layers also differ with respect to one another. In this case, the first layers contain a layer having a first dopant concentration, a further layer having a second dopant concentration and other layers each having a third dopant concentration.

Preferably, the dopant concentration of one layer of the two layers is at least 1.5× as high as the dopant concentration of the other layer of the two layers.

Preferably, the dopant concentration of one layer of the two layers is greater than 10¹⁸ cm⁻³. Particularly preferably, the dopant concentration of one layer of the two layers lies is 2×10¹⁸ cm⁻³ to 6×10¹⁸ cm⁻³.

Preferably, the dopant concentration of the other layer of the two layers is less than 10¹⁸ cm⁻³. Particularly preferably, the dopant concentration of the other layer of the two layers is 3×10¹⁷ cm⁻³ is 7×10¹⁷ cm⁻³.

Preferably, the lateral extent of the oxidized regions of the two layers whose concentration of the dopant is different has a lateral extent that is different from the lateral extent of the other first layers.

Different concentrations of the dopants in two layers having the same composition within the first resonator mirror are suitable for adapting the extent of the oxidized regions of the layers to given requirements in the best possible manner. In particular, the given requirements made of the first layers of the first resonator mirror are not identical over the entire lateral extent, for example, because the current path through the semiconductor body is intended to be delimited to the central region. This fact can be taken into account with a dopant concentration that is not constant over the first layers of the first resonator mirror and, consequently, with different lateral extents of the oxidized regions of the first layers.

Preferably, the oxidized regions of the two layers whose concentration of the dopant is different have a different lateral extent.

In this case, the first layers of the first resonator mirror contain a layer having an oxidized region having a first lateral extent, a further layer having an oxidized region having a second lateral extent, and other layers each having oxidized regions having a third lateral extent.

A first resonator mirror formed in this way advantageously delimits the current flow through the first resonator mirror, and thus through the semiconductor body, locally. In particular, with the two layers whose lateral extent of the oxidized regions differs from one another and from the further first layers, it is possible both to delimit the current flow substantially to the central region of the semiconductor body and to reduce the lateral current spreading within the first layers of the first resonator mirror. In this case, the reduction of the lateral current spreading can be obtained by the second lateral extent of the oxidized region of the further layer.

Preferably, the lateral extent of the oxidized region of one layer of the two layers whose concentration of the dopant is different is at least 2× as large as the lateral extent of the oxidized region of the other layer of the two layers.

Preferably, the oxidized regions of the first layers each have a lateral extent having, apart from the two layers having a different dopant concentration, a deviation of less than 200 nm.

Consequently, the first layers, apart from the two layers having a different dopant concentration, have a similar, substantially identical dopant concentration, and thus a similar, substantially identical lateral extent of the oxidized regions.

Preferably, the surface emitting semiconductor laser component is an electrically pumped semiconductor laser component.

Preferably, the active zone has an active layer. The active layer has a pn junction, a double heterostructure, a single quantum well structure (SQW, single quantum well) or a multi quantum well structure (MQW, multi quantum well) for generating radiation. In this case, the designation quantum well structure does not exhibit any significance with regard to the dimensionality of the quantization. It therefore encompasses, inter alia, quantum wells, quantum wires and quantum dots and any combination of these structures.

The semiconductor body is preferably a semiconductor chip. The semiconductor body is particularly preferably a thin-film semiconductor chip. In the context of the application, a thin-film semiconductor chip is considered to be a semiconductor chip during whose production the growth substrate, onto which a semiconductor layer sequence comprising a semiconductor body of the thin-film semiconductor chip was grown, for example, epitaxially, has been stripped away. The semiconductor chips can each be connected to a carrier substrate, which is different from the growth substrate for the semiconductor layer sequence of the semiconductor body.

The carrier substrate is advantageously not subject to the comparatively stringent requirements that have to be satisfied by a growth substrate, for instance with regard to the crystal structure. Consequently, more materials are available for the selection of the material of the carrier substrate than for the selection of the material of the growth substrate. The carrier substrate can therefore be chosen comparatively freely with regard to advantageous properties, such as high thermal and/or electrical conductivity. By way of example, such a carrier substrate can contain a semiconductor material that is different from the growth substrate or a metal and/or a heat sink.

Preferably, the semiconductor body is based on a nitride, phosphide or arsenide compound semiconductor. “Based on nitride, phosphide or arsenide compound semiconductors” means that the active epitaxial layer sequence or at least one layer thereof comprises a III/V semiconductor material having the composition InₓGa_{y}Al_{1-x-y}P, InₓGa_{y}Al_{1-x-y}N or InₓGa_{y}Al_{1-x-y}As, where 0≦x≦1, 0≦y≦1 and x+y≦1.

Preferably, the two layers whose concentration of the dopant is different have a different thickness.

As a result of the different dopant concentration of the two layers, preferably the lateral extent of the oxidized regions can be influenced in a targeted manner. In addition, the lateral extent of the oxidized regions can be influenced in a targeted manner by the different thicknesses of these two layers. Preferably, both the dopant concentration and the thickness of the two layers are set in such a way as to result in a desired lateral extent of the oxidized regions of the two layers.

The oxidized regions are preferably arranged in the edge region of the semiconductor body. As a result, the current flow is advantageously delimited locally. In particular, the current conductivity is low in the edge region of the semiconductor body.

The first and the second resonator mirror preferably have alternately stacked layers, wherein the alternately stacked layers have, in particular, different refractive indices.

The first and the second resonator mirror are preferably embodied as a Bragg mirror. The first resonator mirror can be embodied as a coupling-out mirror for the radiation from the resonator and for this purpose preferably has a lower reflectivity than the second resonator mirror.

The radiation generated in the active zone can be reflected between the first resonator mirror and the second resonator mirror such that in the resonator a radiation field is formed for the generation of coherent radiation (laser radiation) by induced emission in the active zone, which can be coupled out from the resonator via the coupling-out mirror, preferably the first resonator mirror.

Preferably, the first resonator mirror has alternately stacked AlAs layers or AlGaAs layers and GaAs layers. Preferably, the first layers contain AlₓGa₁₋ₓAs, where 0.8≦x≦1. Particularly preferably, the first layers contain AlₓGa₁₋ₓAs, where 0.95≦x≦1. The second layers preferably contain Al_{y}Ga_{1-y}As, where 0≦y≦0.5, particularly preferably where 0≦y≦0.2.

Preferably, the first resonator mirror has alternately stacked first layers and second layers, wherein a transition layer is respectively arranged between a first layer and a second layer. The transition layer preferably has an aluminum content that lies between the aluminum content of the first layer and the aluminum content of the second layer. In this case, the transition layer can preferably have an aluminum content that varies perpendicularly to the lateral extent of the transition layer, for example, an aluminum content that increases or decreases parabolically, linearly or in stepped fashion.

Further preferably, the aluminum content of the at least one layer of the first layers having a dopant concentration that is different from the dopant concentration of the other first layers differs from the aluminum content of the other first layers. Preferably, the first layers have two layers which differ from the other first layers in terms of the dopant concentration and particularly preferably from one another in terms of the dopant concentration, wherein the aluminum content of the two layers differs from the aluminum content of the other first layers. Particularly preferably, the aluminum content of the two layers is higher than the aluminum content of the other first layers.

Particularly preferably, the aluminum content of the two layers also differs from one another. In this case, the first layers contain a layer having a first aluminum content, a further layer having a second aluminum content, and other layers each having a third aluminum content.

Preferably, the lateral extent of the oxidized regions of the two layers having a dopant concentration that is different from the dopant concentration of the other first layers is influenced in a targeted manner by a different dopant concentration of the two layers, by a different thickness of these two layers and, in addition, by a different aluminum content of the two layers. Preferably, both the dopant concentration, the thickness and the aluminum content of the two layers are set in such a way as to result in a desired lateral extent of the oxidized regions of the two layers.

Preferably, the at least one layer of the first resonator mirror whose concentration of the dopant is different has a p-type doping in each case. Particularly preferably, the at least one layer has a carbon doping.

The layers of the second resonator mirror preferably have an n-type doping in each case. Preferably, only the first resonator mirror has oxidized regions.

We surprisingly found that the magnitude of the dopant concentration of the layers of the second resonator mirror influences the lateral extent of the oxidized regions of the first layers of the first resonator mirror. A high dopant concentration in the second resonator mirror leads to very small lateral extents of the oxidized regions of the first layers of the first resonator mirror. We found that this effect is independent of the used dopant of the second resonator mirror.

The extent of the oxidized regions in the first layers is accordingly dependent on the doping profile of the entire semiconductor body. The oxidation process is accordingly dependent on the dopant concentration of the layers of the second resonator mirror and the dopant concentration of the first and the second layers of the first resonator mirror.

As a result of a targeted setting of the dopant concentration of the first layers of the first resonator mirror, in the case of a desired lateral extent of the oxidized regions of the first layers, the dopant concentration of the second resonator mirror can advantageously remain unchanged. A reduction, for example, of the dopant concentration in the second resonator mirror is not necessary, as a result of which disadvantageous changes in the entire doping profile are advantageously not required. An improved reproducibility of the lateral extent of the oxidized regions and an improved oxidation homogeneity are thus advantageously possible.

A method for producing a surface emitting semiconductor laser component comprises, in particular, the following steps:

epitaxial growth of a semiconductor body onto a growth substrate comprising a first resonator mirror, a second resonator mirror and an active zone provided for generating radiation, wherein the first resonator mirror has alternately stacked first layers having a first composition and second layers having a second composition, wherein, during the growth, at least one dopant is introduced into the first layers, wherein at least one layer of the first layers has a dopant concentration that is different from the dopant concentration of the other first layers, and

partial oxidation of the first layers by an oxidation process, thus giving rise to oxidized regions each having a lateral extent.

Advantageous configurations of the method arise analogously to the advantageous configurations of the semiconductor laser component, and vice-versa.

Preferably, the dopant concentration of the first layers of the first resonator mirror, in the case of a predefined dopant concentration of the layers of the second resonator mirror, is set in such a way that the oxidized regions of the first layers have a desired lateral extent.

The dopant concentration of the layers of the second resonator mirror can be predefined, while the dopant concentration of the first layers of the first resonator mirror is set depending on the envisaged lateral extent of the oxidized regions. As a result of a targeted setting of the dopant concentration of the first layers of the first resonator mirror, the oxidation process can advantageously be controlled, without in this case intervening in the doping profile of the remaining layers of the semiconductor body.

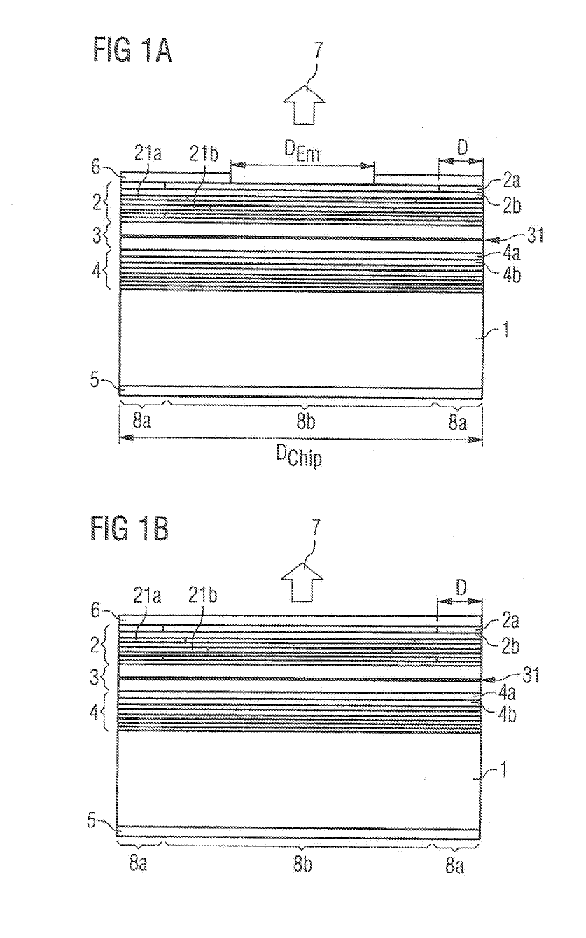

Further features, advantages, preferred configurations and expediences of the surface emitting semiconductor laser component and of the method for producing the latter will become apparent from the examples explained below in conjunction with FIGS. 1 to 3.

Identical or identically acting constituent parts are in each case provided with the same reference symbols. The constituent parts illustrated and also the size relationships of the constituent parts among one another should not be regarded as true to scale.

FIG. 1A illustrates a surface emitting semiconductor laser component which has a vertical emission direction 7 and is provided for generating laser radiation by an internal optical resonator.

A semiconductor body having a first resonator mirror 2, a second resonator mirror 4 and an active zone 3 is arranged on a substrate 1. The first resonator mirror 2 has in each case alternately stacked first layers 2a having a first composition and second layers 2b having a second composition. The second resonator mirror 4 likewise has alternately stacked layers 4a, 4b. The active zone 3 has an active layer 31 provided for generating radiation. The first resonator mirror 2, the active zone 3 and the second resonator mirror 4 each have a lateral main extension direction.

The semiconductor body is preferably a semiconductor chip, particularly preferably as a thin-film semiconductor chip.

The substrate 1 can be formed from the growth substrate or a fragment of the growth substrate of the semiconductor body, on which firstly the second resonator mirror 4 and then the active zone 3 were grown, preferably epitaxially. As an alternative, the substrate 1 can be different from the growth substrate of the semiconductor body. The substrate 1 is preferably embodied in n-conducting fashion.

The active layer 31 of the active zone 3 preferably has a pn junction, a double hetero-structure, a single quantum well structure or a multi quantum well structure for generating radiation. Preferably, the semiconductor body is based on a nitride, phosphide or arsenide compound semiconductor. By way of example, the substrate 1 contains GaAs and the semiconductor body is based on the material system InₓGa_{y}Al_{1-x-y}As where 0≦x, y≦1 and x+y≦1.

The second resonator mirror 4 is arranged between the active zone 3 and the substrate 1, wherein the second resonator mirror 4 forms together with the first resonator mirror 2 an optical resonator for the radiation generated in the active zone 3. The first resonator mirror 4 and the second resonator mirror 2 are preferably integrated together with the active zone 3 into the semiconductor body of the semiconductor laser component.

The first resonator mirror 2 is a coupling-out mirror for the laser radiation generated in the resonator by induced emission and has a lower reflectivity than the second resonator mirror 4.

Radiation 7 generated in the active zone 3 is emitted from the semiconductor body in a vertical direction.

Preferably, the first resonator mirror 2 and the second resonator mirror 4 are in each case a Bragg mirror.

The second resonator mirror 4 has a plurality of semiconductor layer pairs 4a, 4b having an advantageously high difference in refractive index. By way of example, a GaAs layer and an AlGaAs layer form a semiconductor layer pair. The plurality of layer pairs in the second resonator mirror 4 is indicated schematically in FIGS. 1A, 1B. Preferably, the second resonator mirror 4 comprises a sequence of 20 to 30 or more semiconductor layer pairs, which results, for example, in a total reflectivity of the second resonator mirror 4 of 99.8 percent or more for the laser radiation.

The first resonator mirror 2 has a plurality of semiconductor layer pairs comprising first layers 2a having a first composition and second layers 2b having a second composition having an advantageously high difference in refractive index. Preferably, the first resonator mirror 2 has first layers 2a composed of AlₓGa₁₋ₓAs, where 0.8≦x≦1, preferably where 0.95≦x≦1, and second layers 2b composed of Al_{y}Ga_{1-y}As, where 0≦y≦0.5, preferably where 0≦y≦0.2. The plurality of layer pairs in the first resonator mirror 2 is indicated schematically in FIGS. 1A, 1B. The layers of the first resonator mirror 2, in the same way as the layers of the second resonator mirror 4 and of the active zone 3, are preferably produced epitaxially.

A first contact layer 5 is arranged on that side of the substrate 1 which is remote from the semiconductor body. The first contact layer 5 preferably contains a metal or a metal alloy.

A second contact layer 6 is preferably arranged on that side of the first resonator mirror 2 which is remote from the active zone 3. The semiconductor laser component is electrically pumped via the first contact layer 5 arranged on that side of the substrate 1 which is remote from the semiconductor body, and the second contact layer 6 arranged on that side of the semiconductor body which lies opposite the substrate 1, the contact layers each containing at least one metal, for example.

Alternatively, the second contact layer 6 can be arranged on that side of the substrate 1 which is remote from the semiconductor body, in particular on that side of the semiconductor body on which the first contact layer 5 is arranged (not illustrated). Contact-making techniques comprising a first and a second contact layer on one side of a semiconductor body are known to those skilled in the art (inter alia, flip-chip semiconductor body) and will not be explained in greater detail at this juncture.

To avoid absorption of the emitted laser radiation in the second contact layer 6, it is the case that, as illustrated in FIG. 1A, the second contact layer 6 is cut out over a central region D_{Em} of the semiconductor body and runs, for example, in ring-like fashion over an edge region of the semiconductor body. The second contact layer 6 can contain, for example, Ti, Au, Pt or alloys comprising at least one of these materials.

Preferably, the layers of the second resonator mirror 4 have an n-type doping. The first and second layers 2a, 2b of the first resonator mirror 2 preferably have a p-type doping. In particular, the first layers 2a of the first resonator mirror 2 have a p-type doping. Particularly preferably, the first layers 2a have a carbon doping.

Furthermore, the first layers 2a of the first resonator mirror 2 have oxidized regions 8a and non-oxidized regions 8b.

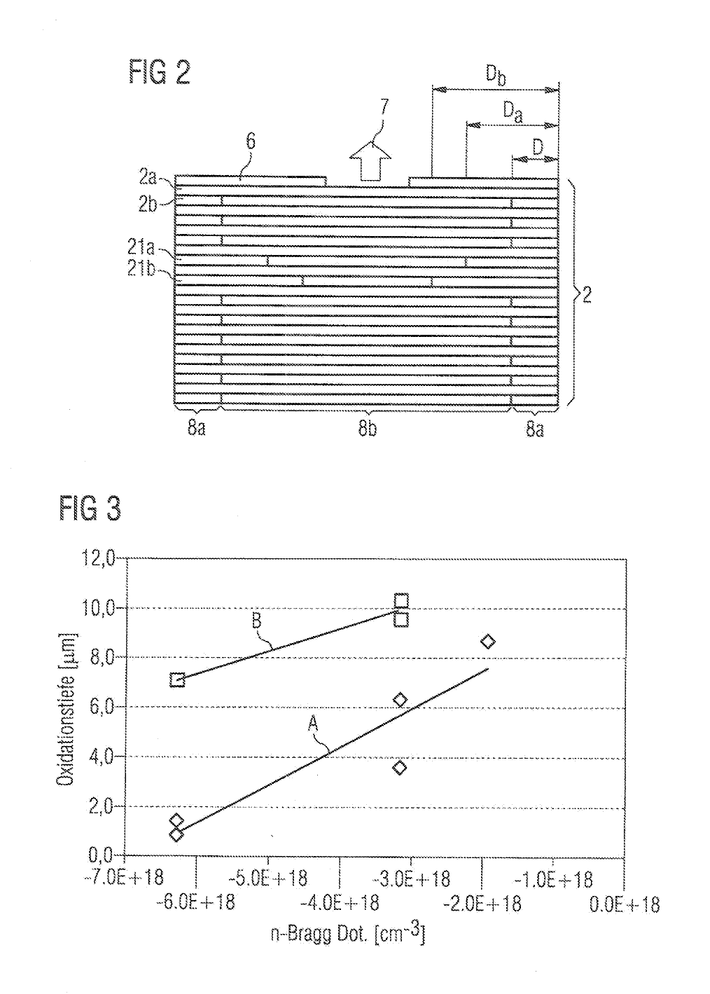

The first resonator mirror 2, in particular the individual first and second layers 2a, 2b, are illustrated in detail in FIG. 2.

Preferably, one layer 21 of the first layers 2a has a dopant concentration that is different from the dopant concentration of the other first layers 2a. In the examples in FIGS. 1A, 1B and 2, two layers 21a, 21b each have a dopant concentration that differs from the other first layers 2a in terms of the dopant concentration.

The dopant concentrations of the two layers 21a, 21b furthermore additionally differ from one another. Consequently, the first layers 2a contain a layer 21a having a first dopant concentration, a further layer 21b having a second dopant concentration, and other layers 2a each having a third dopant concentration.

Furthermore, the two layers 21a, 21b having a dopant concentration that is different from the other first layers 2a and from one another have a lateral extent Dₐ, D_{b} of the oxidized regions 8a that is different from the lateral extent D of the oxidized regions 8a of the other first layers 2a.

The dopant concentration influences the oxidation process in the first layers 2a, in particular the lateral extent of the oxidized regions 8a. By to dopant concentration in the first layers 2a of the first resonator mirror 2, it is accordingly possible to influence the lateral extent of the oxidized regions 8a in these layers 2a. Essential component properties such as, for example, the series resistance, threshold voltage, threshold current and efficiency can therefore be advantageously influenced depending on the dopant concentration in the first layers 2a.

Furthermore, the oxidation homogeneity can be improved as a result of a targeted setting of the dopant concentration in the first layers 2a of the first resonator mirror. As a result of an improved oxidation homogeneity in the first layers 2a of the first resonator mirror, the component properties of the semiconductor laser component can likewise furthermore be advantageously improved.

As a result of the different dopant concentrations, and thus the different lateral extent of the oxidized regions 8a, in the first layers 2a of the first resonator mirror 2, the current flow through the first resonator mirror 2, and thus through the semiconductor body, can advantageously be delimited locally. In particular, with the two layers 21a, 21b whose dopant concentration differs from one another and from the further first layers 2a, it is possible to delimit the current flow substantially to the central region D_{Em} of the semiconductor body and to reduce the lateral current spreading within the first layers 2a of the first resonator mirror 2.

The dopant concentration of one layer 21a of the two layers 2a is preferably at least 1.5× as high as the dopant concentration of the other layer 21b of the two layers 2a.

Preferably, the dopant concentration of one layer of the two layers is 2×10¹⁸ cm⁻³ to 6×10¹⁸ cm⁻³. Particularly preferably, the dopant concentration of the other layer of the two layers is 3×10¹⁷ cm³ to 7×10¹⁷ cm³.

In each case, the second layers 2b of the first resonator mirror preferably have no oxidized regions. In particular, the layers of the first resonator mirror 2 which preferably contain AlₓGa₁₋ₓAs where 0.95≦x≦1 have oxidized regions. Furthermore, the layers 2a having oxidized regions 8a have regions 8b that are not oxidized.

The oxidized regions 8a are preferably arranged in the edge region of the semiconductor body. By way of example, the oxidized regions 8a run in ring-like fashion over the edge region of the semiconductor body.

As a result of the oxidation process, the first layers 2a lose current conductivity in these regions 8a. As a result, the current flow through the semiconductor body can advantageously be delimited locally. In particular, the semiconductor body has, in the edge region, virtually no or at least a lower current flow than in the non-oxidized regions.

Electrical pumping of the edge region of the active zone 3 that is arranged below the oxidized regions 8a is advantageously avoided on account of the lower current conductivity—compared with the non-oxidized regions 8b—of the first layers 2a of the first resonator mirror.

The current flow is accordingly influenced by the oxidized regions 8a of the first layers 2a, in particular preferably formed in the central region D_{Em} of the semiconductor body.

Preferably, the lateral extent of the oxidized regions 8a of the two layers 21a, 21b whose concentration of the dopant is different has a lateral extent Dₐ that is different from the lateral extent of the other first layers 2a and from one another.

The oxidized regions of the first layers 2a of the first resonator mirror 2 each have a lateral extent D. Preferably, in this case two layers 21a, 21b have a lateral extent Dₐ, D_{b} that is different from the lateral extent D of the other first layers 2a.

The different lateral extents D, Dₐ, D_{b} are preferably obtained by the different dopant concentrations in these layers 2a, 21a, 21b. Preferably, the first layers 2a of the first resonator mirror 2 have a dopant concentration such that the oxidized regions 8a each have an envisaged lateral extent D, Dₐ, D_{b}. Preferably, the dopant concentration of the first layers 2a, 21a, 21b of the first resonator mirror 2, in the case of a predefined dopant concentration of the layers 4a, 4b of the second resonator mirror 4, is set in such a way that the oxidized regions 8a each have the envisaged lateral extent D, Dₐ, D_{b}.

Preferably, the n-type doping of the layers 4a, 4b of the second resonator mirror 4 can be fixedly predefined, while the p-type doping of the first layers 2a of the first resonator mirror 2 is set in such a way that the oxidized regions 8a have a desired lateral extent D, Dₐ, D_{b}.

Preferably, only the p-doped first resonator mirror 2 has first layers 2a having oxidized regions 8a. The oxidation process is dependent on the entire doping profile of the semiconductor body. The lateral extent D, Da, Db of the oxidized regions 8a can thus be fixed by a setting of the dopant concentration of the p-type dopant in the first layers 2a of the first resonator mirror 2.

Preferably, the two layers 21a, 21b whose concentration of the dopant is different have a different thickness (not illustrated).

The lateral extent D, Dₐ, D_{b} of the oxidized regions 8a can preferably be influenced in a targeted manner by the different dopant concentration of the two layers 21a, 21b. In addition, the lateral extent D, Dₐ, D_{b} of the oxidized regions 8a can be influenced in a targeted manner by the different thickness of these two layers 21a, 21b. Preferably, the dopant concentration and the thickness of the two layers 21a, 21b are set in such a way as to result in a desired lateral extent D, Dₐ, D_{b} of the oxidized regions 8a of the two layers 21a, 21b.

Furthermore, the lateral extent D, Dₐ, D_{b} of the oxidized regions 8a can be influenced in a targeted manner by a different aluminum content of the two layers 21a, 21b with respect to one another and with respect to the aluminum content of the other first layers 2a. Particularly preferably, the dopant concentration, the thickness and the aluminum content of the two layers 21a, 21b are set in such a way to result in a desired lateral extent D, Dₐ, D_{b} of the oxidized regions 8a of the two layers 21a, 21b.

A second contact layer 6 is arranged on the first resonator mirror 2 in regions. Preferably, the second contact layer 6 is arranged in the edge region of the semiconductor body. In particular, the central region D_{Em} thus has no second contact layer 6.

The second contact layer 6 preferably has a larger lateral extent than the oxidized regions 8a of the first layers 2a of the first resonator mirror 2. An overlap of the second contact layer 6 over the oxidized regions 8a thus arises. In this case, the second contact layer 6 can have a smaller or a larger lateral extent than the oxidized regions 8a of the two layers 21a, 21b whose concentration of the dopant is different. It is also conceivable for the second contact layer 6 to have a smaller lateral extent than the oxidized region 8a of one of the two layers 21b and to have a larger lateral extent than the oxidized region 8a of the second layer 21a. In this case, the lateral extent of the second contact layer 6 lies in a range between the lateral extent of the oxidized region 8a of one of the two layers 21b and the lateral extent of the oxidized region 8a of the second layer 21a.

Preferably, the current fed in is injected into the active zone predominantly via the non-oxidized region 8b of the first layers 2a of the first resonator mirror 2. In the edge region of the semiconductor body having the oxidized regions 8a, current injection is predominantly avoided in the active zone 3 on account of the low current conductivity of the oxidized regions 8a of the first layers 2a. Consequently, a radiative recombination, or generation of radiation, on account of the comparatively low transverse conductivity of the oxidized regions 8a, takes place predominantly in the non-oxidized regions 8b of the active zone 3. The current path of the pump current in the semiconductor body can thus be determined by the lateral extent of the oxidized regions 8a of the first layers 2a.

The example in FIG. 1B differs from the example in FIG. 1A by virtue of a whole-area second contact layer 6. An electrically conductive contact layer 6 is accordingly arranged on the first resonator mirror 2 over the whole area for the electrical connection of the semiconductor laser component.

In this case, the laser radiation is coupled out through the second contact layer 6. The second contact layer 6 accordingly has to have at least partly transparent properties for the radiation 7 generated by the active zone 3. In particular, the absorption of the laser radiation emitted by the active zone 3 in the second contact layer 6 is low, preferably less than 40 percent, particularly preferably less than 20 percent.

In the example in FIG. 1B, the second contact layer 6 preferably comprises a transparent conductive oxide. Transparent conductive oxides (TCO) are transparent conductive materials, generally metal oxides such as, for example, zinc oxide, tin oxide, cadmium oxide, titanium oxide, indium oxide or indium tin oxide (ITO). Alongside binary metal-oxygen compounds such as, for example, ZnO, SnO₂ or In₂O₃, ternary metal-oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and can also be p- or n-doped.

FIG. 3 illustrates a diagram showing the dependence of the lateral extent D of the oxidized regions 8a of the first layers on the charge carrier density in the n-doped second resonator mirror 4. The diagram illustrates the lateral extent D of the oxidized regions (oxidation depth) in the p-doped first resonator mirror 2 (μm), against the dopant concentration of the second resonator mirror 4 (cm⁻³). The values of the dopant concentration of the n-doped second resonator mirror 4 are plotted along the abscissa of the diagram. The values of the lateral extent of the oxidized regions of the first layers of the p-doped first resonator mirror 2 are plotted on the ordinate.

Graph A illustrated in the diagram indicates values for which the first layers of the p-doped first resonator mirror 2 have an active doping. Graph B in the diagram shows values for which the first layers of the p-doped first resonator mirror 2 have an intrinsic doping. In particular, in this case, the first layers 2a have a doping which arises during the growth process of the individual layers of the semiconductor body, without being introduced actively.

As illustrated in the diagram, the lateral extent of the oxidized regions of the first layers 2a of the first resonator mirror 2 is surprisingly dependent on the dopant concentration of the layers of the second resonator mirror 4. The extent D of the oxidized regions 8a is accordingly dependent on the doping profile of the entire semiconductor body. In particular, the dopant concentration of the layers of the second resonator mirror 4 influences the surface charge of the first layers 2a of the first resonator mirror 2. The surface charge of the first layers 2a in turn influences the oxidation process in the first layers 2a. The oxidation process is accordingly dependent on the dopant concentration of the layers of the second resonator mirror 4 and the dopant concentration of the first and of the second layers of the first resonator mirror 2.

As a result of a targeted setting of the dopant concentration of the first layers 2a of the first resonator mirror 2, in the case of a desired lateral extent of the oxidized regions 8a of the first layers 2a, the dopant concentration of the second resonator mirror 4 can advantageously remain unchanged.

This disclosure is not restricted to the examples by the description on the basis thereof, but rather encompasses any novel feature and also any combination of features, which in particular includes any combination of features in the appended claims, even if the feature or combination itself is not explicitly specified in the claims or examples.

1. A surface emitting semiconductor laser component having a vertical emission direction comprising:
a semiconductor body having a first resonator mirror;
a second resonator mirror; and
an active zone that generates radiation, wherein
the first resonator mirror has alternately stacked first layers having a first composition and second layers having a second composition,
the first layers have oxidized regions,
at least the first layers each contain a dopant, and
at least one layer of the first layers has a dopant concentration different from the dopant concentration of the other first layers.

2. The component according to claim 1, wherein the oxidized region of the at least one layer has a lateral extent that is different from a lateral extent of the other first layers.

3. The component according to claim 2, wherein the lateral extent of the oxidized regions of the at least one layer deviates from the lateral extent of the oxidized regions of the other first layers by at least 1 μm.

4. The component according to claim 1, wherein two layers of the first layers have a dopant concentration different from the dopant concentration of the other first layers.

5. The component according to claim 4, wherein the dopant concentration of one layer of the two layers is at least 1.5× as high as the dopant concentration of the other layer of the two layers.

6. The component according to claim 5, wherein the dopant concentration of one layer of the two layers is greater than 10¹⁸ cm⁻³.

7. The component according to claim 5, wherein the dopant concentration of the other layer of the two layers is less than 10¹⁸ cm⁻³.

8. The component according to claim 4, wherein the lateral extent of the oxidized regions of the two layers deviates from the lateral extent of the oxidized regions of the other first layers.

9. The component according to claim 4, wherein the lateral extent of the oxidized region of one layer of the two layers is at least 2× as large as the lateral extent of the oxidized region of the other layer of the two layers.

10. The component according to claim 4, wherein the two layers have a different thickness.

11. The component according to claim 1, wherein, the at least one layer has a p-type doping.

12. The component according to claim 1, wherein the at least one layer has a C doping.

13. The component according to claim 1, wherein the oxidized regions are arranged in the edge region of the semiconductor body.

14. The component according to claim 1, wherein the first layers contain AlₓGa₁₋ₓAs, where 0.8≦x≦1.

15. The component according to claim 1, wherein the second layers contain Al_{y}Ga_{1-y}As, where 0≦y≦0.5.

16. The component according to claim 6, wherein the dopant concentration of the other layer of the two layers is less than 10¹⁸ cm⁻³.
